(19) United States
(12) Patent Application Publication
(10) Pub. No.: US 2023/0140547 A1
(43) Pub. Date: May 4, 2023

(54) Input Output Banks of a Programmable Logic Device

(71) Applicant: Intel Corporation, Santa Clara, CA (US)

(72) Inventors: Terence Magee, San Francisco, CA (US); Jeffrey Schulz, Milpitas, CA (US); Arun Patel, Toronto (CA)

(21) Appl. No.: 18/091,626

(22) Filed: Dec. 30, 2022

(51) Int. Cl. G06F 13/16; G06F 11/10

(52) U.S. Cl. CPC G06F 13/1689; G06F 11/1044

(57) ABSTRACT

A system includes a programmable logic fabric core of an integrated circuit device and an IO interface communicatively coupled to the programmable logic fabric core. The IO interface includes multiple IO banks to implement a memory channel. Each IO bank includes a memory controller to control memory accesses of a memory device over the memory channel and multiple physical layer and IOs circuits to provide connections between the memory controller and the memory device. The respective memory controller may receive only a portion of data to be sent over the memory channel or multiple memory controllers may each receive all data to be sent over the memory channel.

### BACKGROUND

The present disclosure relates generally to input output (IO) banks for semiconductor devices. More particularly, the present disclosure relates to IO banks for programmable logic devices.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits, such as field programmable gate arrays (FPGAs) are programmed to perform one or more particular functions. The FPGAs (or other programmable logic devices) may utilize IOs to enable data to be input to or output from the FPGAs. For instance, the IOs may provide an interface to a memory device coupled to the FPGA. In the context of FPGAs' IOs and its synchronous dynamic random accessible memory (SDRAM) interfaces, it may be advantageous to create a modular bank of IOs such that the number of IOs in the banks is small enough so FPGAs using different numbers of IOs can be easily built by adding or removing banks. The smaller the IO count per bank, the easier it is to hit the desired per-FPGA IO count which its market requires, without under counting or increasing silicon cost. Furthermore, these IOs may be for more than double data rate (DDR) SDRAM interfacing including simple general-purpose IO applications that may use different and/or varying numbers of IOs. The IO bank may contain IOs, phase-locked-loops (PLLs), and one or more DDR SDRAM memory controllers. The IO bank may be large enough for some implementations (e.g., 16-bit channel) but may need to be grouped with adjacent IO banks for other implementations (e.g., 32-bit channel). However, a bank-to-bank timing closure may be used in such implementations, but bank-to-bank timing closure may add development steps that may increase development costs and/or increases in time-to-market.

Furthermore, if a main controller may drive multiple IOs, the IOs may need high-speed timing closure between the main controller and the IO banks that the main controller is not part of. These IO banks may be grouped into a complex subsystem, but organization into these multiple subsystems may have to be built grouping different numbers (e.g., 1 to many) IO banks to achieve a desired IO count.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a diagram of programmable fabric of the integrated circuit device of FIG. 1, in accordance with an embodiment of the present disclosure;

FIG. 4 is a block diagram of an IO bank providing a 16-bit memory channel, in accordance with an embodiment of the present disclosure;

FIG. 5 is a block diagram of two IO banks providing a 32-bit memory channel using inter-channel signals, in accordance with an embodiment of the present disclosure;

FIG. 6 is a block diagram of multiple IO banks providing a 64-bit plus error correction code (ECC) memory channel using multiple memory controllers receiving only a portion of the data being transferred, in accordance with an embodiment of the present disclosure;

FIG. 7 is a block diagram of multiple IO banks providing two 16-bit plus ECC memory channels using multiple memory controllers receiving all the data being transferred for each channel, in accordance with an embodiment of the present disclosure;

FIG. 8 is a block diagram of multiple IO banks providing a 32-bit plus ECC memory channel using multiple memory controllers receiving all of the data being transferred over the memory channel, in accordance with an embodiment of the present disclosure;

FIG. 9 is a block diagram of multiple IO banks providing a 32-bit plus ECC memory channel using multiple memory controllers receiving all of the data being transferred, in accordance with an embodiment of the present disclosure;

FIG. 10 is a block diagram of multiple IO banks providing a memory channel with a schematic diagram showing additional details of the IO banks, in accordance with an embodiment of the present disclosure; and

FIG. 11 is a block diagram of a data processing system, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As previously noted, FPGAs (or other programmable logic devices) may benefit from flexibility in using IOs in IO banks that maintain flexibility in deployment in the FPGAs. As discussed below, such IO banks contain IOs, PLLs, and one of more DDR SDRAM memory controllers. As discussed below, building a small enough IO bank that is self-contained such that it can be part of a larger DDR SDRAM channel solution enables such flexibility without the IO banks needing to interact with neighboring IO banks in a manner that requires bank-to-bank timing closure. Thus, the FPGA may be developed without the delays and/or costs necessary to satisfy bank-to-bank timing closure requirement.

The FPGA IO flexibility may enable an IO to support multiple types of interfaces. For example, an FPGA that supports both low-power DDR type 5 SDRAM (LPDDR5) and DDR type 4 SDRAM (DDR4) channels have an IO bank that contains enough IOs with a memory controller and PLLs to support 32-bit wide LPDDR5. However, to support a DDR4 channel, the FPGA may group multiple banks together to realize enough IOs for the 64 data bits plus 8 bits of ECC that a DDR4 DIMM requires. This may be true for multiple other types of interfaces, such as DDR type 5 SDRAM (DDR5) and non-SDRAM interfaces. Further, one controller out of the multiple controllers across multiple banks may be selected as a main controller to launch and capture data across many IO banks. Further still, FPGAs flexibility may allow the user to select any controller in any IO bank to be main controller. To enable such flexibility, the FPGA may utilize a high-speed timing closure between the main controller and all the IO banks, which in turn, requires building an intermediate and complex subsystem of multiple IO banks until it becomes self-contained and can be drop-in integrated at chip-level. Further, the larger intermediate subsystem may break the ability to obtain to an FPGA IO count to within one IO bank of granularity of the desired IO count. Instead of such complex subsystems, the IO banks may be at least somewhat independent, as discussed below, to remove such high-speed timing closure requirements.

Furthermore, the independent nature of the IOs discussed below may also reduce its area and/or material costs by reducing the overall memory controller size per bank. Since the main controller may be selectable out of all the memory controllers in a bank grouping means that every memory controller must support the widest SDRAM channel needs. At the same time, the FPGA is to support many narrow channels so these memory controllers also scale down to narrow widths. One option is to use wide memory controllers that inefficiently use resources when implementing narrow channels. As noted below, replacing such wide controllers with narrower controllers may be used for wide and narrow channels by causing the narrow controllers to be in lock-step with each other to realize wider channels thus saving area over FPGAs with overly large memory controllers.

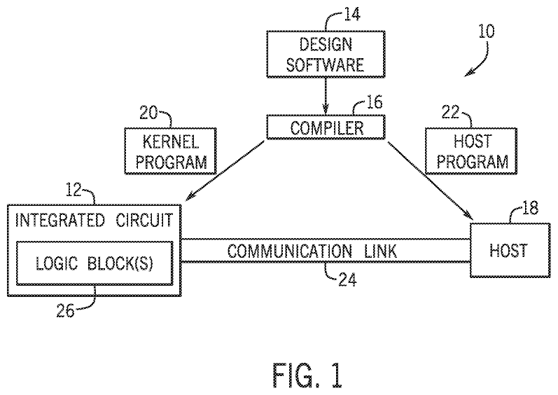

With the foregoing in mind, FIG. 1 illustrates a block diagram of a system 10 that may implement arithmetic operations. A designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OPENCL® program, which may enable the designer to more efficiently and easily provide programming instructions to configure a set of programmable logic cells for the integrated circuit device 12 without specific knowledge of low-level hardware description languages (e.g., Verilog or VHDL). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of a logic block 26 on the integrated circuit device 12. The logic block 26 may include circuitry and/or other logic elements and may be configured to implement arithmetic operations, such as addition and multiplication.

The designer may use the design software 14 to generate and/or to specify a low-level program, such as the low-level hardware description languages described above. Further, in some embodiments, the system 10 may be implemented without a separate host program 22. Moreover, in some embodiments, the techniques described herein may be implemented in circuitry as a non-programmable circuit design. Thus, embodiments described herein are intended to be illustrative and not limiting.

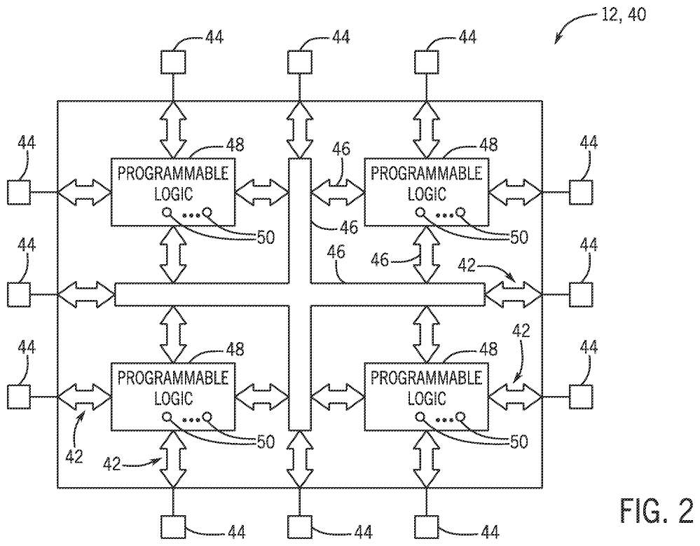

Turning now to a more detailed discussion of the integrated circuit device 12, FIG. 2 is a block diagram of an example of the integrated circuit device 12 as a programmable logic device, such as a field-programmable gate array (FPGA). Further, it should be understood that the integrated circuit device 12 may be any other suitable type of programmable logic device (e.g., an ASIC and/or application-specific standard product). The integrated circuit device 12 may have input/output (IO) circuitry 42 for driving signals off device and for receiving signals from other devices via input/output pins 44. Interconnection resources 46, such as global and local vertical and horizontal conductive lines and buses, and/or configuration resources (e.g., hardwired couplings, logical couplings not implemented by user logic), may be used to route signals on integrated circuit device 12. Additionally, interconnection resources 46 may include fixed interconnects (conductive lines) and programmable interconnects (i.e., programmable connections between respective fixed interconnects). Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program programmable elements 50. In general, programmable elements 50 may be based on any suitable programmable technology, such as fuses, antifuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. For instance, in some embodiments, the output signals may be applied to the gates of metal-oxide-semiconductor (MOS) transistors within the programmable logic 48.

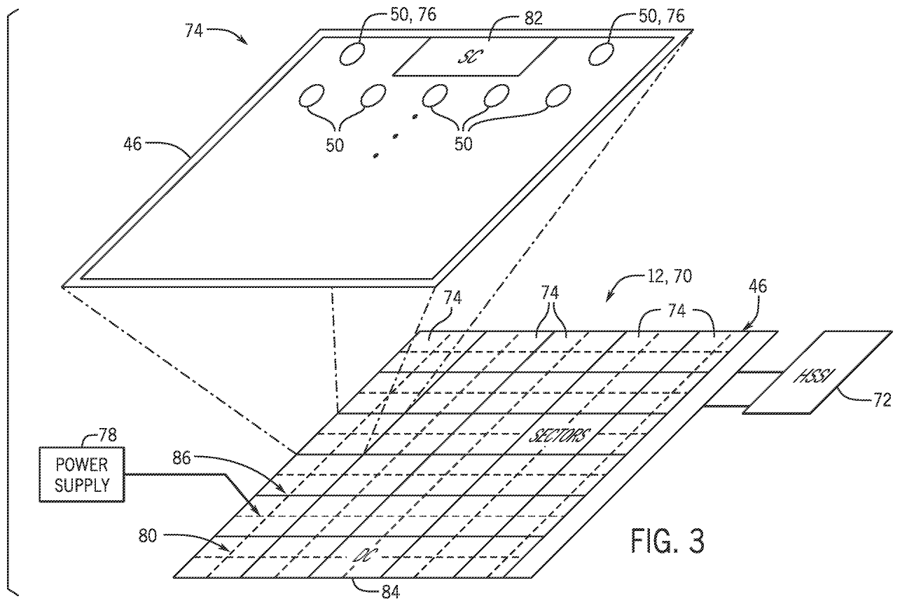

The integrated circuit device 12 may include any programmable logic device such as a field programmable gate array (FPGA) 70, as shown in FIG. 3. For the purposes of this example, the FPGA 70 is referred to as an FPGA, though it should be understood that the device may be any suitable type of programmable logic device (e.g., an application-specific integrated circuit and/r application-specific standard product). In one example, the FPGA 70 is a sectorized FPGA of the type described in U.S. Patent Publication No. 2016/0049941, “Programmable Circuit Having Multiple Sectors,” which is incorporated by reference in its entirety for all purposes. The FPGA 70 may be formed on a single plane. Additionally or alternatively, the FPGA 70 may be a three-dimensional FPGA having a base die and a fabric die of the type described in U.S. Pat. No. 10,833,679, “Multi-Purpose Interface for Configuration Data and User Fabric Data,” which is incorporated by reference in its entirety for all purposes.

In the example of FIG. 3, the FPGA 70 may include transceiver 72 that may include and/or use input/output circuitry, such as input/output circuitry 42 in FIG. 2, for driving signals off the FPGA 70 and for receiving signals from other devices. Interconnection resources 46 may be used to route signals, such as clock or data signals, through the FPGA 70. The FPGA 70 is sectorized, meaning that programmable logic resources may be distributed through a number of discrete programmable logic sectors 74. Programmable logic sectors 74 may include a number of programmable logic elements 50 having operations defined by configuration memory 76 (e.g., CRAM). A power supply 78 may provide a source of voltage (e.g., supply voltage) and current to a power distribution network (PDN) 80 that distributes electrical power to the various components of the FPGA 70. Operating the circuitry of the FPGA 70 causes power to be drawn from the power distribution network 80.

There may be any suitable number of programmable logic sectors 74 on the FPGA 70. Indeed, while 29 programmable logic sectors 74 are shown here, it should be appreciated that more or fewer may appear in an actual implementation (e.g., in some cases, on the order of 50, 100, 500, 1000, 5000, 10,000, 50,000 or 100,000 sectors or more). Programmable logic sectors 74 may include a sector controller (SC) 82 that controls operation of the programmable logic sector 74. Sector controllers 82 may be in communication with a device controller (DC) 84.

Sector controllers 82 may accept commands and data from the device controller 84 and may read data from and write data into its configuration memory 76 based on control signals from the device controller 84. In addition to these operations, the sector controller 82 may be augmented with numerous additional capabilities. For example, such capabilities may include locally sequencing reads and writes to implement error detection and correction on the configuration memory 76 and sequencing test control signals to effect various test modes.

The sector controllers 82 and the device controller 84 may be implemented as state machines and/or processors. For example, operations of the sector controllers 82 or the device controller 84 may be implemented as a separate routine in a memory containing a control program. This control program memory may be fixed in a read-only memory (ROM) or stored in a writable memory, such as random-access memory (RAM). The ROM may have a size larger than would be used to store only one copy of each routine. This may allow routines to have multiple variants depending on “modes” the local controller may be placed into. When the control program memory is implemented as RAM, the RAM may be written with new routines to implement new operations and functionality into the programmable logic sectors 74. This may provide usable extensibility in an efficient and easily understood way. This may be useful because new commands could bring about large amounts of local activity within the sector at the expense of only a small amount of communication between the device controller 84 and the sector controllers 82.

Sector controllers 82 thus may communicate with the device controller 84, which may coordinate the operations of the sector controllers 82 and convey commands initiated from outside the FPGA 70. To support this communication, the interconnection resources 46 may act as a network between the device controller 84 and sector controllers 82. The interconnection resources 46 may support a wide variety of signals between the device controller 84 and sector controllers 82. In one example, these signals may be transmitted as communication packets.

The use of configuration memory 76 based on RAM technology as described herein is intended to be only one example. Moreover, configuration memory 76 may be distributed (e.g., as RAM cells) throughout the various programmable logic sectors 74 of the FPGA 70. The configuration memory 76 may provide a corresponding static control output signal that controls the state of an associated programmable logic element 50 or programmable component of the interconnection resources 46. The output signals of the configuration memory 76 may be applied to the gates of metal-oxide-semiconductor (MOS) transistors that control the states of the programmable logic elements 50 or programmable components of the interconnection resources 46.

As discussed above, some embodiments of the programmable logic fabric may be configured using indirect configuration techniques. For example, an external host device may communicate configuration data packets to configuration management hardware of the FPGA 70. The data packets may be communicated internally using data paths and specific firmware, which are generally customized for communicating the configuration data packets and may be based on particular host device drivers (e.g., for compatibility). Customization may further be associated with specific device tape outs, often resulting in high costs for the specific tape outs and/or reduced salability of the FPGA 70.

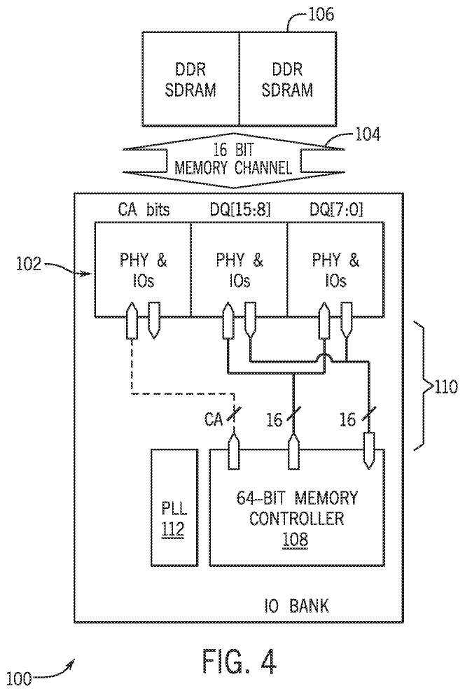

As previously noted, FPGAs may be deployed flexibly. As part of that flexible deployment, FPGAs may support interfacing with multiple DDR memory types. This flexibility presents potential usage of a mix of wide and narrow controller SDRAM channels. For example, a DDR4 DIMM channel requires 64 bits of data plus 8 bits of ECC with one controller communicating with nine ×8 SDRAMs or 18×4 SDRAMs on a single rank dual in-line memory module (DIMM). In contrast, DDR5 has a reduced channel width of 32 bits plus ECC. Moreover, LPDDR5 can use also 32 bit-wide channels but without additional ECC. However, LPDDR5 may use a more common channel width of 16 bits. Memory interfaces use data bits and command address (CA) bits to control the type of accesses and the location of such accesses. DDR5 and LPDDR5 have reduced CA widths when compared to DDR4. All of these different variations translates to a wide variation in IO counts and the number of IO banks the memory controller communicates with to realize these channels in an FPGA. At the same time and as noted above, reducing the IO bank size improves the ability for FPGAs to scale out its IO counts across devices in a family for multiple different deployments. For scalability and flexibility an IO Bank contains at least one memory controller. FIG. 4 is a block diagram of an IO bank 100 that includes three PHY & IOs circuits 102 to implement a 16-bit memory channel 104 between the FPGA and two DDR SDRAMs 106. The PHY in the PHY and IOs circuits 102 refer to the physical layer that captures and launches data between itself and a memory controller 108 in a synchronous manner using a clock common to the memory controller 108 via controller-PHY connections 110 that include timed paths. The PHY and IOs circuits 102 also send/receive data from the IOs synchronous with a clock (Ck) shared with the DDR SDRAMs 106.

Note that data (DQ) refers to the JEDEC defined SDRAM data bits and their data strobes (DQS) used to assist in capturing the transferred data between the DDR SDRAMs and the FPGA's memory subsystem. As previously mentioned, CA refers to the command, clocking and addressing sent to the DDR SDRAMs from the FPGA's memory subsystem. Each of the PHY & IOs circuits 102 may be generic and may service moving DQ data or CA. The number of IOs per PHY/PHY & IOs circuits 102 may vary between different implementations of the PHY & IOs circuits 102. For instance, the illustrated embodiment includes enough IOs to communicate with a ×8 DRAM or two ×4 DRAMs. However, the number of IOs per PHY & IOs circuits 102 may be any other suitable number. If using eight IOs, two PHY & IOs circuits 102 may be used for DDR5 and three PHY & IOs circuits 102 for DDR4.

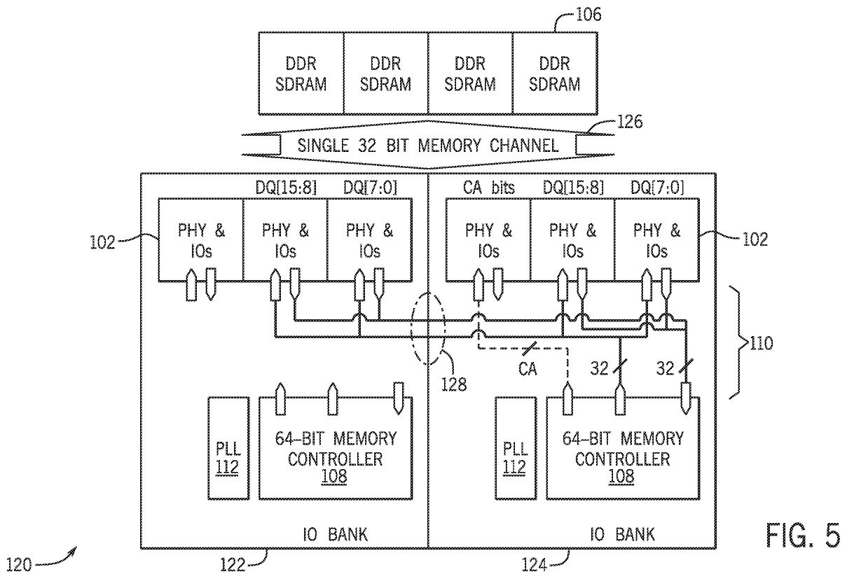

Since the IO bank 100 includes enough IOs to implement a narrow channel, multiple IO banks 100 may be joined together to implement a wider channel. FIG. 5 shows a block diagram of a system 120 that includes IO banks 122 and 124 to realize a 32-bit memory channel 126 between the FPGA and 4 DDR SDRAMs 106 by having the memory controller 108 of the IO bank 124 drive the PHY & IOs circuits 102 of both IO bank 122 and IO bank 124. There are now inter-bank signals 128 crossing the two banks that are internally synchronous and must be timing closed against the controller clock frequency across IO banks. In other words, this pair of IO banks 122 and 124 needs to be integrated and timing closed together before integrating this new subsystem at the chip-level. This problem is exacerbated as the channel width increases. Consider the case of DDR4 that needs 64-bits of DQ, plus ECC, plus a larger CA bus compared to LPDDR5. In such an instance, there may be four IO banks with three inter-bank signals 128 causing all of IO banks needing to be integrated together to timing close before a final full-chip integration of the four IO bank 122 system.

Besides the added complexity and design effort to build such an intermediate subsystem before full-chip integration, other issues exist in the integrated memory subsystem concept of FIG. 5. First, this approach requires wider memory controllers in every IO bank than the individual bank needs, especially due to the required FPGA flexibility to select which memory controller is driving the interface. Second, in order to get to per-bank granularity when building out FPGAs of varying IO counts, one may need to build additional subsystems, such that the required number of IO banks on the chip to serve market needs. For example, if 5 IO banks are to be used without a bigger die cost of using two IO Banks with three IOs subsystem, a subsystem with an IO bank with three IOs may be used along with an IO bank with two IOs may be used.

An alternative to the integrated subsystem of FIG. 5 is to cause the FPGA user logic to use each of the memory controllers 108 in parallel with divided data. Such a technique provides multiple benefits. First, the wide controllers (e.g., 64-bit) can be replaced with narrow controllers (e.g., 24-bit) with less resource consumption. The divided/split data occurs due to the user interface communicating with all four controllers by spreading the read and write data across the multiple memory controllers when the channel is wider than a single IO bank. This enables the appropriate data bits to make their way to and from the appropriate SDRAMs via individual controllers. To accomplish the spread, the user logic/design implemented in the FPGA will break-up write data to be sent to memory and re-assemble read data to be read from memory, accordingly. For the CA bits, the user logic/design implemented in the FPGA broadcasts this to every memory controller 108. For example, for a write operation, the user logic/design implemented in the FPGA will broadcast a write command along with the memory address to every memory controller 108. The memory controllers 108 behave in identical fashion on every clock cycle when presented with identical control and address. In some embodiments, an appropriate subset of CA bits from CA bus outputs of respective memory controller(s) 108 is selectively passed on to the appropriate PHY & IOs circuits 102.

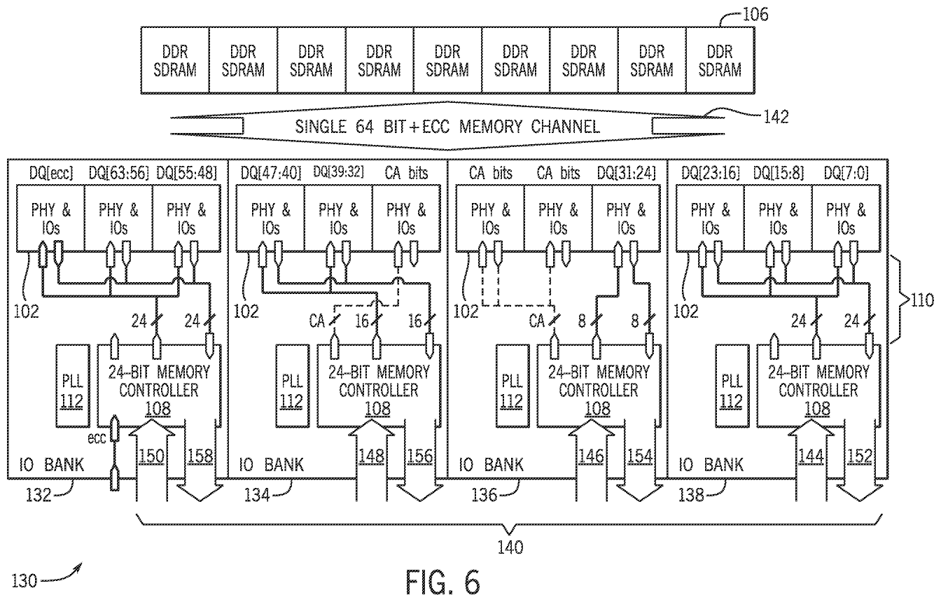

FIG. 6 is a block diagram of a system 130 including IO banks 132, 134, 136, and 138 act as a set 140 to implement a 64 bit plus error control code (ECC) (e.g., 8 bits) memory channel 142 to nine DDR SDRAMs 106. As illustrated, the memory controllers 108 may be narrower than the memory channel 142 unlike the disclosure above related to FIG. 5. As noted above, these narrower memory controllers 108 may be used since each of the IO banks 132, 134, 136, and 138 of the set 140 receive only a portion of the data (e.g., DQ, CA, ECC) to be transmitted over the memory channel 142. Indeed, the IO bank 138 receives data 144 from the user logic/design implemented in the FPGA, the IO bank 136 receives data 146 from the user logic/design implemented in the FPGA, the IO bank 134 receives data 148 from the user logic/design implemented in the FPGA, and the IO bank 132 receives data 150 from the user logic/design implemented in the FPGA. In the illustrated embodiment, the data 144 includes the CA bits and 24 DQ bits [23:0]. The data 146 includes the CA bits and 8 DQ bits [31:24]. The data 148 includes the CA bits and 16 DQ bits [47:32]. The data 150 includes the CA bits, 16 DQ bits [63:48], and ECC bits. Although in some FPGA and/or other memory controllers, the memory controller may calculate ECC based on the data, in the illustrated embodiment, none of the memory controllers 108 receives all of the DQ data. Thus, none of the memory controllers 108 may calculate the ECC. Instead, the user logic/design implemented in the FPGA may calculate the ECC and send it to the memory controller 108 of the IO bank 132 in the data 150. For example, the data 144, 146, 148, and 150 may be the divided data of a write operation bound for the DDR SDRAMs 106s.

For data incoming to the user logic/design implemented in the FPGA from the DDR SDRAMs 106, each of the memory controllers 108 may also only receive a portion of the data. For instance, the data 152, 154, 156, and 158 may contain similar respective bits that the data 144, 146, 148, and 150 except that the data is in-bound to the user logic/design implemented in the FPGA from the DDR SDRAMs 106 (e.g., read operations) rather than vice versa (e.g., write operations).

Although the system 130 shows specific bits (e.g., CA, DQ, and ECC) in particular locations using specific IOs, the data may be divided in any suitable manner with the bits being arranged in any suitable division.

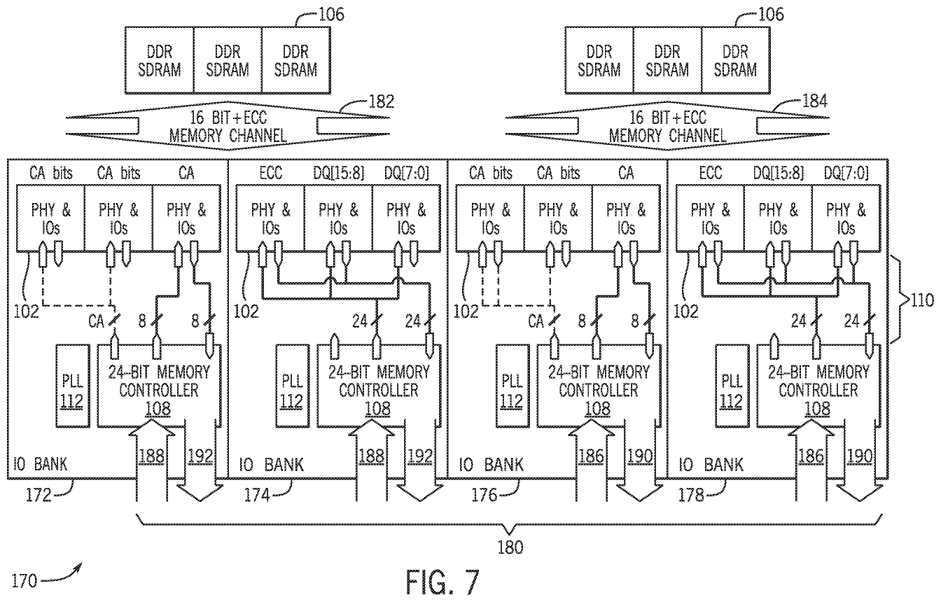

The same flexible IO banks of FIG. 6 may be used to implement narrower memory channels. For instance, FIG. 7 is a block diagram of a system 130 that uses IO banks 172, 174, 176, and 178 of a set 180 the same as the system 170 uses the IO banks 132, 134, 136, and 138 of the set 140. The set 180 functions the similar as the set 140 except that there are two narrower 16 bit plus ECC channels 182 and 184 for the set 180 instead of a single wider (e.g., 64-bit) channel for the set 140. Furthermore, since the memory channels 182 and 184 are not wider than the memory controllers 108, the data may not be divided within a channel. Specifically, the IO banks 178 and 176 receive data 186 from the user logic/design implemented in the FPGA, and the IO banks 174 and 172 receives data 188 from the user logic/design implemented in the FPGA. In the illustrated embodiment, the data 186 includes the CA bits and all DQ bits [15:0] for the memory channel 184. Similarly, the data 188 includes the CA bits and all DQ bits [15:0] for the memory channel 182. Since the memory controllers 108 of the IO bank 178 and the IO bank 174 receive all data for the their respective channels, the memory controllers 108 of the IO banks 178 and 174 may calculate their respective ECC values to be transmitted to the respective DDR SDRAMs 106.

For data incoming to the user logic/design implemented in the FPGA from the DDR SDRAMs 106, each of the memory controllers 108 may receive all of the data for their respective channels. For instance, the data 190 and 192 may contain similar respective bits that the data 186 and 188 except that the data is in-bound to the user logic/design implemented in the FPGA from the DDR SDRAMs 106 (e.g., read operations) rather than vice versa (e.g., write operations).

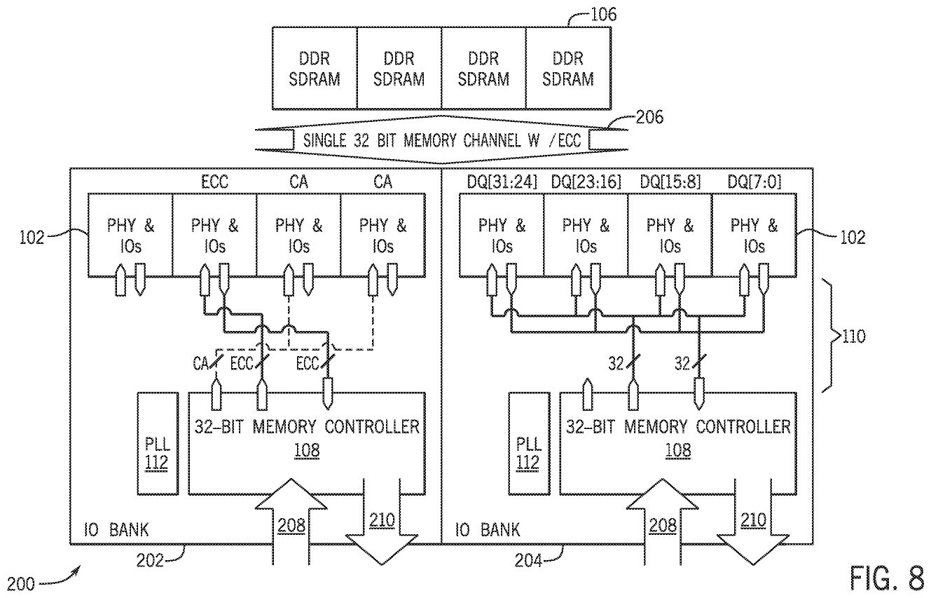

This mix of protocol support may impact the size and make-up of the IO banks in the FPGA to maximize granularity and/or self-containment of certain features within an IO bank. For example, if we consider DDR5 to be an emphasized protocol, a 24-bit Memory Controller may not be the ideal solution. Thus, alternative numbers of bits may be used. FIG. 8 shows a system 200 that may be more suited for certain protocols (e.g., DDR5). IO banks 202 and 204 include more PHY & IOs circuits 102 with 32-bit memory controllers 108 enabling a 32 bit plus ECC memory channel 206. The system 200 also enables using a memory controller-generated ECC using two IO banks 202 and 204 with the memory controller 108 of the IO bank 202 generating the ECC and CA bits while the memory controller 108 of the IO bank 204 transfers the DQ to the five DDR SDRAMs 106. Outgoing data 208 and incoming data 210 may be the same between the two different IO banks 202 and 204.

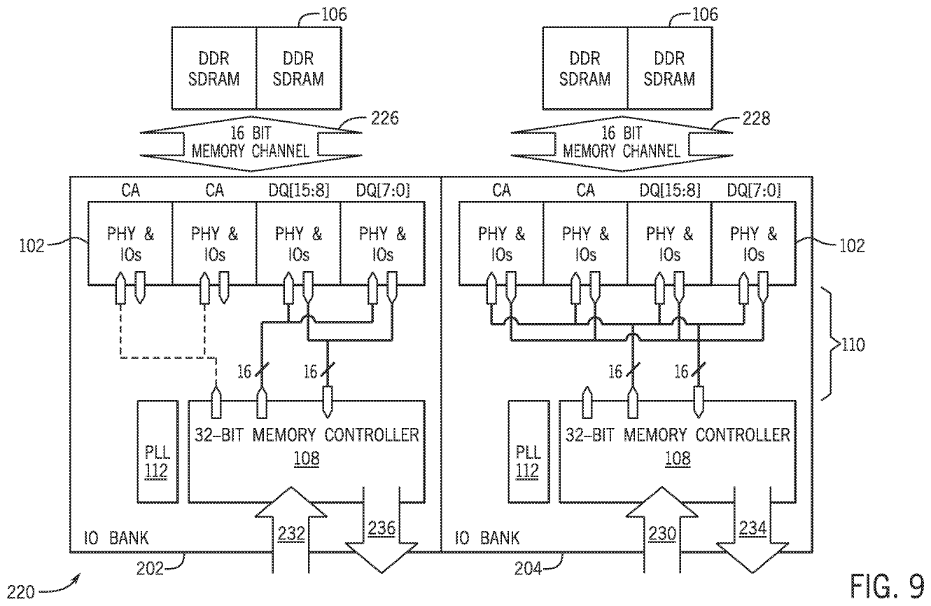

These larger IO banks 202 and 204 can, in turn, realize DDR4 with only 3 IO Banks. Further, this IO Bank can support two 16-bits DDR5, LPDDR4, or LPDDR5 channels without ECC as well as similar LPDDR4 and LPDDR5 combinations. For instance, FIG. 9 illustrates a system 220 with the IO Banks 202 and 204 realizing two 16-bit memory channels 226 and 228. Since the memory channels 226 and 228 are different channels, outgoing data 230 and 232 may be different between the different IO banks 202 and 204. Similarly, the incoming data 234 and 236 may be different between the different IO banks 202 and 204.

Lock-stepping of the memory controllers 108 used to implement a channel is achieved by the SDRAM channels being closed-loop synchronous systems from the memory controllers 108 to the SDRAM 106 and back. Further, SDRAM specs require the memory controllers 108 to manipulate clock, CA, and DQ arrival times at all SDRAMs 106 of the same channel to achieve such synchronicity. Specifically, the CA bits are clocked into SDRAM by a common CK clock. Write data is clocked into all SDRAMs 106 by respective write DQS signals based on a write latency (WL) worth of CK clock cycles after a write command. A JEDEC defined training step called write leveling ensures that DQS's are aligned with CK as seen by each SDRAM to achieve this. The controller and PHYs provide this capability. Similarly, each SDRAM 106 returns read data based on a read latency (RL) worth of CK cycles after receiving a read command. Furthermore, in some embodiments, the write leveling of two memory controllers 108 of a same channel may delay transmissions different numbers of cycles after write leveling. To ensure that these memory controllers 108 stay synchronized during such events, the memory controllers 108 may share the number of cycles discovered in write leveling to delay both memory controllers 108 by the maximum delay.

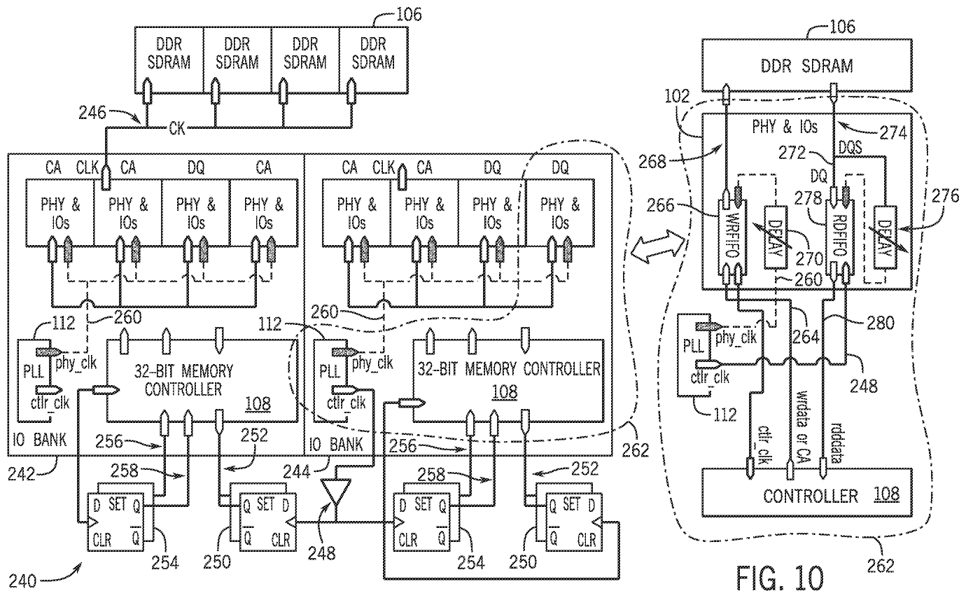

FIG. 10 further illustrates this lockstep function using a system 240 including IO banks 242 and 244 to implement a channel to four DDR SDRAMs 106. SDRAM-side of the PHY & IOs circuits 102 is controlled using CK 246 as discussed previously. Between the memory controllers 108 and the FPGA core, a common controller clock (ctlr_clk) 248 is transmitted from one PLL 112 of the lock-stepped banks (e.g., IO bank 244 as illustrated). This common controller clock 248 is made the root clock that controls timing for user logic/designs implemented in the FPGA core and all memory controllers 108 of the channel. This ensures the memory controllers 108 will be locked synchronously to each other.

For each IO bank, this common controller clock 248 is used to clock latches 250 that latch in read data 252 from the memory controller 108 bound for the user logic/designs implemented in the FPGA core using latches. Similarly, this common controller clock 248 is used to clock latches 254 used to latch write data 256 and CA bits 258 from the user logic/designs implemented in the FPGA core bound for the memory controller 108.

Within each IO bank 242 and 244, between the memory controller 108 and its PHY & IOs circuits 102, a PHY clock (phy_clk) 260 may be used. This PHY clock 260 may be used to control timing through the PHY & IOs circuits 102. For instance, region 262 shows a more detailed version of an embodiment of the PHY and IOs circuits 102 where clock domains change between the local PHY clocks 260 and the common controller clock 248 between the PHY and IOs circuits 102 and the memory controller 108. Specifically, as illustrated, outgoing data (wrdata or CA) 264 is transmitted from the memory controller 108 to a write FIFO (WRFIFO) 266 based on the common controller clock 248. The outgoing data 264 may be write data or CA data. Outgoing data 268 is read out of the WRFIFO 266 based on the PHY clock 260. Thus, the WRFIFO 266 enables the outgoing data 264 to be in a domain of the common controller clock 248 while the outgoing data 268 is in a domain of the PHY clock 260. In other words, the WRFIFO 266 moves outgoing data between clock domains. As previously noted, the communication with the DDR SDRAMs 106 from the PHY and IOs circuits 102 is synchronous and may be trained (e.g., using write leveling). A programmable delay 270 may be used to manipulate the phase of the PHY clock 260 to achieve synchronization with DDR SDRAM 106 and align DQ/DQS to synchronize with the CK 246.

The DDR SDRAM 106 transmits a read DQ 272 carrying read data and a read DQS 274 to assist in the PHY & IOs circuits 102 capturing the read data. The PHY & IOs circuits 102 may include a programmable delay 276 to provide synchronicity with the DDR SDRAM 106. A read FIFO (RDFIFO) 278 moves the SDRAM read DQ and DQS back to the common controller clock 248 domain.

Finally, for the controllers to behave similarly all read and write data movement and scheduling decisions may run synchronously within the memory controller 108 under a single clock, the common controller clock 248. The scheduling rules and circuits of the memory controllers 108 may be identical for all memory controllers 108. In order words, the internal design of the memory controllers 108 for processing commands to and from the SDRAM may be identical even if the data widths vary.

Depending on the controller design and its feature set, other aspects may be considered to ensure lock-step between the memory controllers 108. For example, memory controllers 108 with asynchronous reset will only present the common controller clock 248 after the reset has been removed so all memory controllers 108 see the same number of edges of the common controller clock 248 after the reset. As another example, writing of programming registers of a memory controller 108 that control its features uses a register interface that has a separate clock asynchronous to the common controller clock 248. In such instances, the memory controller 108 may present the common controller clock 248 only after programming is complete and to remove and re-present said clock during programming occurrences. In a further example, the SDRAM refresh rate may be adjusted by the memory controller 108 in some DDR protocols based on a temperature of a connected DDR SDRAM 106. If the DDR SDRAMs 106 of a channel have different temperatures, this can lead the memory controllers 108 to have different refresh rates. To mitigate such situations, a host (e.g., external microprocessor) may poll DDR SDRAM 106 temperatures and perform register updates as previously noted using the common user logic.

Although the foregoing examples discuss specific numbers of IOs (e.g., bits) per PHY and IOs circuits 102, specific numbers of PHY and IOs circuits 102 per IO bank, specific numbers of IO banks per channel, specific numbers of bits per channel, specific number of DDR SDRAMs 106 per bits/channels, and specific organizations of the bits in a channel, other arrangements/embodiments may be consistent with the foregoing discussion. For example, some integrated circuit devices 12 may include different numbers of IOs (e.g., bits) per PHY and IOs circuits 102, different numbers of PHY and IOs circuits 102 per IO bank, different numbers of IO banks per channel, different numbers of bits per channel, different number of DDR SDRAMs 106 per bits/channels, and/or different organizations of the bits in a channel without straying from the scope of the present disclosure.

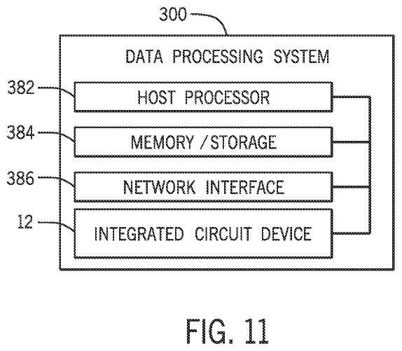

Furthermore, the integrated circuit device 12 may generally be a data processing system or a component, such as an FPGA, included in a data processing system 300. For example, the integrated circuit device 12 may be a component of a data processing system 300 shown in FIG. 11. The data processing system 300 may include a host processor 382 (e.g., a central-processing unit (CPU)), memory and/or storage circuitry 384, and a network interface 386. The data processing system 300 may include more or fewer components (e.g., electronic display, user interface structures, application specific integrated circuits (ASICs)). The host processor 382 may include any suitable processor, such as an INTEL® Xeon® processor or a reduced-instruction processor (e.g., a reduced instruction set computer (RISC), an Advanced RISC Machine (ARM) processor) that may manage a data processing request for the data processing system 300 (e.g., to perform debugging, data analysis, encryption, decryption, machine learning, video processing, voice recognition, image recognition, data compression, database search ranking, bioinformatics, network security pattern identification, spatial navigation, or the like). The memory and/or storage circuitry 384 may include random access memory (RAM), read-only memory (ROM), one or more hard drives, flash memory, or the like. The memory and/or storage circuitry 384 may hold data to be processed by the data processing system 300. In some cases, the memory and/or storage circuitry 384 may also store configuration programs (bitstreams) for programming the integrated circuit device 12. The network interface 386 may allow the data processing system 300 to communicate with other electronic devices. The data processing system 300 may include several different packages or may be contained within a single package on a single package substrate.

In one example, the data processing system 300 may be part of a data center that processes a variety of different requests. For instance, the data processing system 300 may receive a data processing request via the network interface 386 to perform acceleration, debugging, error detection, data analysis, encryption, decryption, machine learning, video processing, voice recognition, image recognition, data compression, database search ranking, bioinformatics, network security pattern identification, spatial navigation, digital signal processing, or some other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

EXAMPLE EMBODIMENT 1. A system, comprising: a programmable logic fabric core of an integrated circuit device; and an IO interface communicatively coupled to the programmable logic fabric core to provide inputs to the programmable logic fabric core and to receive outputs from the programmable logic fabric core, wherein the IO interface comprises: a plurality of IO banks to implement a memory channel, wherein each IO bank of the plurality of IO banks comprises: a memory controller to control memory accesses of a memory device over the memory channel; and a plurality of physical layer and IOs circuits to provide connections between the memory controller and the memory device, wherein the memory channel is wider than the respective memory controllers, and each respective memory controller is to receive only a portion of data to be sent over the memory channel.

EXAMPLE EMBODIMENT 2. The system of example embodiment 1, wherein the programmable logic fabric is configured to calculate ECC and send the ECC to a respective memory controller of one of the plurality of IO banks to be transmitted to the memory device.

EXAMPLE EMBODIMENT 3. The system of example embodiment 1, comprising:
the integrated circuit device; and the memory device.

EXAMPLE EMBODIMENT 4. The system of example embodiment 1, wherein each of the memory controllers is to use a common controller clock to capture data from the programmable logic fabric core.

EXAMPLE EMBODIMENT 5. The system of example embodiment 4, wherein the plurality of IO banks comprise a plurality of phase locked loops (PLL).

EXAMPLE EMBODIMENT 6. The system of example embodiment 5, wherein a PLL of the plurality of PLLs in one of the IO banks of the plurality of IO banks is to provide the common controller clock to memory controllers of the other IO banks of the plurality of IO banks.

EXAMPLE EMBODIMENT 7. The system of example embodiment 5, wherein each of the plurality of IO banks is to use respective independent local clocks from the plurality of PLLs.

EXAMPLE EMBODIMENT 8. The system of example embodiment 7, wherein the plurality of IO banks each respectively comprise: a write FIFO to push in write data from a respective memory controller using the common controller clock and to pop write data to the memory device using a respective independent local clock; and a read FIFO to push in read data from the memory device using a read data strobe from the memory device and to pop read data to the memory controller using the common controller clock.

EXAMPLE EMBODIMENT 9. The system of example embodiment 8, wherein the plurality of IO banks each respectively comprise: a first programmable delay to delay the respective independent local clock to synchronize pops of write data from the write FIFO to the memory device with timing of the memory device; and a second programmable delay to the read data strobe to synchronize pops of read data from the read FIFO with timing of the memory device.

EXAMPLE EMBODIMENT 10. The system of example embodiment 1, wherein the programmable logic fabric is configured to divide the data to be sent over the memory channel between the respective memory controllers of the plurality of IO banks.

EXAMPLE EMBODIMENT 11. A system, comprising: a programmable logic fabric core of an integrated circuit device; and an IO interface communicatively coupled to the programmable logic fabric core to provide inputs to the programmable logic fabric core and to receive outputs from the programmable logic fabric core, wherein the IO interface comprises: a plurality of IO banks to implement a memory channel, wherein each IO bank of the plurality of IO banks comprises: a memory controller to control memory accesses of a memory device over the memory channel; and a plurality of physical layer and IOs circuits to provide connections between the memory controller and the memory device, wherein each respective memory controller of the memory controllers is to receive all data sent over the memory channel.

EXAMPLE EMBODIMENT 12. The system of example embodiment 11, wherein the one of the memory controllers of the memory controllers is to calculate ECC and to send the ECC to the memory device over the memory channel.

EXAMPLE EMBODIMENT 13. The system of example embodiment 11, wherein each of the memory controllers is to use a common controller clock to capture data from the programmable logic fabric core.

EXAMPLE EMBODIMENT 14. The system of example embodiment 13, wherein the plurality of IO banks comprise a plurality of phase locked loops (PLL).

EXAMPLE EMBODIMENT 15. The system of example embodiment 14, wherein a PLL of the plurality of PLLs in one of the IO banks of the plurality of IO banks is to provide the common controller clock to the memory controllers of the other IO banks of the plurality of IO banks.

EXAMPLE EMBODIMENT 16. The system of example embodiment 14, wherein each of the plurality of IO banks is to use respective independent local clocks from the plurality of PLLs.

EXAMPLE EMBODIMENT 17. The system of example embodiment 16, wherein the plurality of IO banks each respectively comprise: a write FIFO to push in write data from a respective memory controller using the common controller clock and to pop write data to the memory device using a respective independent local clock; and a read FIFO to push in read data from the memory device using a read data strobe from the memory device and to pop read data to the memory controller using the common controller clock.

EXAMPLE EMBODIMENT 18. The system of example embodiment 17, wherein the plurality of IO banks each respectively comprise: a first programmable delay to delay the respective independent local clock to synchronize pops of write data from the write FIFO to the memory device with timing of the memory device; and a second programmable delay to the read data strobe to synchronize pops of read data from the read FIFO with timing of the memory device.

EXAMPLE EMBODIMENT 19. A system, comprising: a programmable logic fabric core of an integrated circuit device; and an IO interface communicatively coupled to the programmable logic fabric core to provide inputs to the programmable logic fabric core and to receive outputs from the programmable logic fabric core, wherein the IO interface comprises: a first plurality of IO banks to implement a first memory channel, wherein each IO bank of the first plurality of IO banks comprises: a first memory controller to control memory accesses of one or more memory devices over the first memory channel; and a first plurality of physical layer and IOs circuits to provide connections between the first memory controller and the one or more memory devices, wherein each respective first memory controller of the first memory controllers is to receive all data sent over the first memory channel; and a second plurality of IO banks to implement a second memory channel, wherein each IO bank of the second plurality of IO banks comprises: a second memory controller to control memory accesses of the one or more memory devices over the second memory channel; and a second plurality of physical layer and IOs circuits to provide connections between the second memory controller and the one or more memory devices, wherein each respective second memory controller of the second memory controllers is to receive all data sent over the second memory channel.

EXAMPLE EMBODIMENT 20. The system of example embodiment 19, wherein one of the first memory controllers of the first memory controllers is to calculate ECC on the data sent over the first memory channel and to send the ECC to the one or more memory devices over the first memory channel, and one of the second memory controllers of the second memory controllers is to calculate ECC on the data sent over the second memory channel and to send the ECC to the one or more memory devices over the second memory channel.

What is claimed is:

1. A system, comprising:
a programmable logic fabric core of an integrated circuit device; and
an IO interface communicatively coupled to the programmable logic fabric core to provide inputs to the programmable logic fabric core and to receive outputs from the programmable logic fabric core, wherein the IO interface comprises:
a plurality of IO banks to implement a memory channel, wherein each IO bank of the plurality of IO banks comprises:
a memory controller to control memory accesses of a memory device over the memory channel; and
a plurality of physical layer and IOs circuits to provide connections between the memory controller and the memory device, wherein the memory channel is wider than the respective memory controllers, and each respective memory controller is to receive only a portion of data to be sent over the memory channel.

2. The system of claim 1, wherein the programmable logic fabric core is configured to calculate ECC and send the ECC to a respective memory controller of one of the plurality of IO banks to be transmitted to the memory device.

3. The system of claim 1, comprising:
the integrated circuit device; and
the memory device.

4. The system of claim 1, wherein each of the memory controllers is to use a common controller clock to capture data from the programmable logic fabric core.

5. The system of claim 4, wherein the plurality of IO banks comprise a plurality of phase locked loops (PLL).

6. The system of claim 5, wherein a PLL of the plurality of PLLs in one of the IO banks of the plurality of IO banks is to provide the common controller clock to memory controllers of the other IO banks of the plurality of IO banks.

7. The system of claim 5, wherein each of the plurality of IO banks is to use respective independent local clocks from the plurality of PLLs.

8. The system of claim 7, wherein the plurality of IO banks each respectively comprise:
a write FIFO to push in write data from a respective memory controller using the common controller clock and to pop write data to the memory device using a respective independent local clock; and
a read FIFO to push in read data from the memory device using a read data strobe from the memory device and to pop read data to the memory controller using the common controller clock.

9. The system of claim 8, wherein the plurality of IO banks each respectively comprise:
a first programmable delay to delay the respective independent local clock to synchronize pops of write data from the write FIFO to the memory device with timing of the memory device; and
a second programmable delay to the read data strobe to synchronize pops of read data from the read FIFO with timing of the memory device.

10. The system of claim 1, wherein the programmable logic fabric core is configured to divide the data to be sent over the memory channel between the respective memory controllers of the plurality of IO banks.

11. A system, comprising:
a programmable logic fabric core of an integrated circuit device; and
an IO interface communicatively coupled to the programmable logic fabric core to provide inputs to the programmable logic fabric core and to receive outputs from the programmable logic fabric core, wherein the IO interface comprises:
a plurality of IO banks to implement a memory channel, wherein each IO bank of the plurality of IO banks comprises:
a memory controller to control memory accesses of a memory device over the memory channel; and
a plurality of physical layer and IOs circuits to provide connections between the memory controller and the memory device, wherein each respective memory controller of the memory controllers is to receive all data sent over the memory channel.

12. The system of claim 11, wherein one of the memory controllers of the memory controllers is to calculate ECC and to send the ECC to the memory device over the memory channel.

13. The system of claim 11, wherein each of the memory controllers is to use a common controller clock to capture data from the programmable logic fabric core.

14. The system of claim 13, wherein the plurality of IO banks comprise a plurality of phase locked loops (PLL).

15. The system of claim 14, wherein a PLL of the plurality of PLLs in one of the IO banks of the plurality of IO banks is to provide the common controller clock to the memory controllers of the other IO banks of the plurality of IO banks.

16. The system of claim 14, wherein each of the plurality of IO banks is to use respective independent local clocks from the plurality of PLLs.

17. The system of claim 16, wherein the plurality of IO banks each respectively comprise:
a write FIFO to push in write data from a respective memory controller using the common controller clock and to pop write data to the memory device using a respective independent local clock; and
a read FIFO to push in read data from the memory device using a read data strobe from the memory device and to pop read data to the memory controller using the common controller clock.

18. The system of claim 17, wherein the plurality of IO banks each respectively comprise:
a first programmable delay to delay the respective independent local clock to synchronize pops of write data from the write FIFO to the memory device with timing of the memory device; and
a second programmable delay to the read data strobe to synchronize pops of read data from the read FIFO with timing of the memory device.

19. A system, comprising:
a programmable logic fabric core of an integrated circuit device; and
an IO interface communicatively coupled to the programmable logic fabric core to provide inputs to the programmable logic fabric core and to receive outputs from the programmable logic fabric core, wherein the IO interface comprises:
a first plurality of IO banks to implement a first memory channel, wherein each IO bank of the first plurality of IO banks comprises:
a first memory controller to control memory accesses of one or more memory devices over the first memory channel; and
a first plurality of physical layer and IOs circuits to provide connections between the first memory controller and the one or more memory devices, wherein each respective first memory controller of the first memory controllers is to receive all data sent over the first memory channel; and
a second plurality of IO banks to implement a second memory channel, wherein each IO bank of the second plurality of IO banks comprises:
a second memory controller to control memory accesses of the one or more memory devices over the second memory channel; and
a second plurality of physical layer and IOs circuits to provide connections between the second memory controller and the one or more memory devices, wherein each respective second memory controller of the second memory controllers is to receive all data sent over the second memory channel.

20. The system of claim 19, wherein one of the first memory controllers of the first memory controllers is to calculate ECC on the data sent over the first memory channel and to send the ECC to the one or more memory devices over the first memory channel, and one of the second memory controllers of the second memory controllers is to calculate ECC on the data sent over the second memory channel and to send the ECC to the one or more memory devices over the second memory channel.
